(19) United States
(12) Patent Application Publication
(10) Pub. No.: US 2006/0197588 A1
(43) Pub. Date: Sep. 7, 2006

(54) FILTERING DEVICE HAVING MULTIPLE INPUTS AND MULTIPLE FEEDBACK PATHS

(76) Inventor: Chia-Jun Chang, Taipei City (TW)

Correspondence Address: NORTH AMERICA INTELLECTUAL PROPERTY CORPORATION, P.O. BOX 506, MERRIFIELD, VA, 22116, US

(21) Appl. No.: 11/307,985

(22) Filed: Mar. 1, 2006

(30) Foreign Application Priority Data
Mar. 3, 2005 (TW) 094106453

(51) Int. Cl. H03K 5/00

(52) U.S. Cl. 327/552

(57) ABSTRACT

A filtering device for filtering N input signals to generate a filtered signal. The filtering device includes an input module and a first circuit. The input module includes at least N impedance components. Each impedance component comprises a first end and a second end. The first end is utilized for receiving one of the N input signals. The first circuit includes a non-virtual ground input end coupled to the second ends of the N impedance components, and an amplifier including a first input end and an output end. There are multiple feedback (MFB) paths between the first input end and the output end. The MFB paths are coupled to the non-virtual ground input end. The output end of the amplifier is utilized for outputting the filtered signal. The first circuit and the input module form an MFB filter.

### BACKGROUND OF THE INVENTION

1. Field of the Invention

The present invention relates to the superposition and filtering of signals, and more particularly, to a filtering device having multiple inputs and multiple feedback (MFB) paths.

2. Description of the Prior Art

Please refer to FIG. 1 and FIG. 2. FIG. 1 is a diagram of a signal superposition circuit 110 according to the prior art. FIG. 2 is a diagram of a multiple feedback (MFB) filter 120 according to the prior art. An output signal Vs of the signal superposition circuit 110 is corresponding to the superposition of input signals Vi1 and Vi2 thereof, and the MFB filter 120 is capable of filtering an input signal Vi_mbf to generate an output signal Vo_mbf. The architecture and operational principles of the signal superposition circuit 110 shown in FIG. 1 and the MFB filter 120 shown in FIG. 2 are well known to those experienced in the art, and therefore will not be explained in further detail.

An input end of the MFB filter 120 can be coupled to an output end of the signal superposition circuit 110 to form a signal processing module. In this situation, the MFB filter 120 receives the output signal Vs of the signal superposition circuit 110 as the input signal Vi_mbf. If each signal processing module is corresponding to a port, a signal processing circuit having N ports probably needs N copies of the signal superposition circuit 110 and N copies of the MFB filter 120. As each signal superposition circuit and each MFB filter respectively have amplifiers, the signal processing circuit mentioned above probably need to have 2N amplifiers. Therefore, if the N is greater, the signal processing circuit having the N ports consumes more current and circuit area.

### SUMMARY OF THE INVENTION

It is an objective of the claimed invention to provide a filtering device having multiple inputs and multiple feedback (MFB) paths.

According to one embodiment of the claimed invention, a filtering device for filtering N input signals to generate a filtered signal is disclosed. The filtering device comprises: an amplifier including an input end and an output end; MFB paths coupling between the input end and the output end; and a plurality of impedance components, where each of the plurality of impedance components comprises a first end coupled to one of the N input signals and a second end coupled to the input end of the amplifier, and N is an integer greater than one. In addition, the voltage drops between the input end and each of the second ends are non-zero.

According to one embodiment of the claimed invention, a filtering device for filtering and superposing a first input signal and a second input signal to generate a filtered signal is disclosed. The filtering device comprises: a first resistor including a first end for receiving the first input signal; a second resistor including a first end for receiving the second input signal; a feedback module coupled to a second ends of the first resistor and a second end of the second resistor for providing MFB paths; and an amplifier including an input end and an output end, where the feedback module is coupled between the input end and the output end of the amplifier, and the output end is utilized for outputting the filtered signal. The filtered signal is received as a feedback signal by the input end of the amplifier via the feedback module. In addition, the voltage drop between the second end of the first or second resistor and the input end is non-zero.

According to one embodiment of the claimed invention, a filtering device for filtering and superposing N input signals to generate a filtered signal is disclosed. The filtering device comprises an input module and a first circuit. The input module comprises N impedance components, where each impedance component comprises a first end and a second end, and the first end is utilized for receiving one of the N input signals. The first circuit comprises: a non-virtual ground input end coupled to second ends of the N impedance components; and an amplifier including a first input end and an output end, where there are MFB paths between the first input end and the output end, the MFB paths are coupled to the non-virtual ground input end, and the output end of the amplifier is utilized for outputting the filtered signal. In addition, the input module and the first circuit form a MFB filter.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a signal superposition circuit according to the prior art.

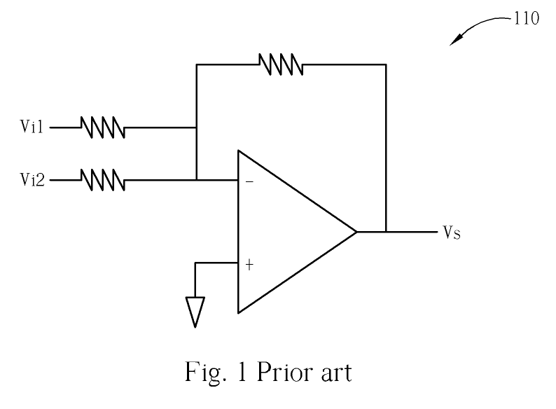

FIG. 2 is a diagram of a multiple feedback (MFB) filter according to the prior art.

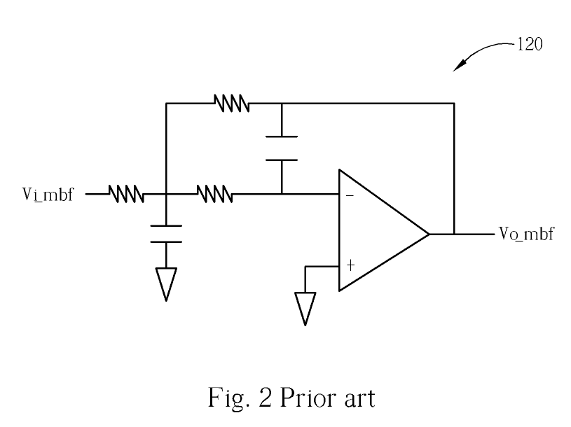

FIG. 3 is a diagram of a filtering device according to one embodiment of the present invention.

### DETAILED DESCRIPTION

Filtering devices of the present invention are capable of performing the function of superposing and filtering a plurality of input signals. According to the present invention, the input signals can be independent of each other/one another or dependent on each other/one another. In addition, the input signals may also have equally weighted values. In this situation, superposition of the input signals means a simple addition operation. According to the present invention, each of the input signals may have specifically weighted values, respectively. In this situation, the superposition of the input signals means a weighted addition operation.

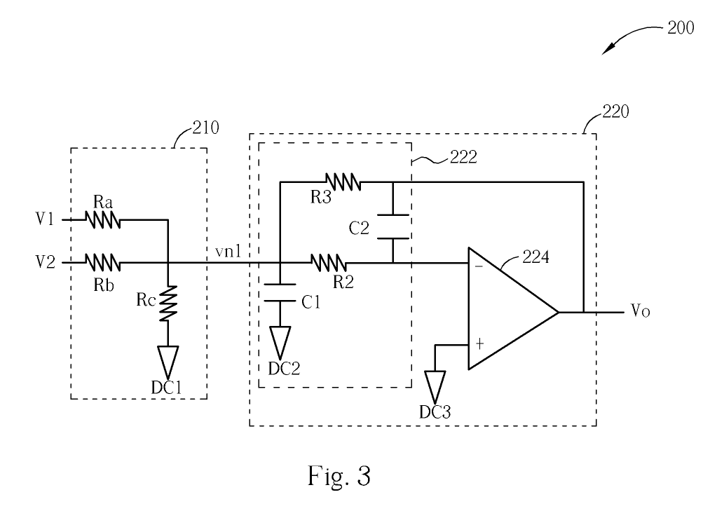

Please refer to FIG. 3. FIG. 3 is a diagram of a filtering device 200 according to one embodiment of the present invention. The filtering device 200 is capable of filtering two input signals V1 and V2 to generate a filtered signal Vo. The filtering device 200 comprises an input module 210 and a first circuit 220. The input module 210 comprises at least two impedance components. Each component includes a first end and a second end. The first end is utilized for receiving one of the two input signals V1 and V2, and the second end is coupled to a non-virtual ground input end vn1 of the first circuit 220. In this embodiment, the two impedance components are two resistors Ra and Rb, which are utilized for receiving the input signals V1 and V2, respectively.

The first circuit 220 comprises a feedback module 222 and an amplifier 224, where the feedback module 222 comprises multiple feedback (MFB) paths, i.e., a plurality of feedback paths. In this embodiment, the feedback module 222 comprises resistors R2 and R3 and capacitors C1 and C2 for providing the amplifier 224 with the MFB paths. In addition, the amplifier 224 of this embodiment is an operational amplifier (Op-Amp). The amplifier 224 includes an output end for outputting the filtered signal Vo. The amplifier 224 further includes a first input end (which is the positive input end in this embodiment) coupled to a direct current (DC) level DC3, and a second input end (which is the negative input end in this embodiment) coupled to the feedback module 222, where the voltage drop between the non-virtual ground input end vn1 and the input end coupled to the feedback module 222 (i.e. the negative input end of the amplifier 224 in this embodiment) is non-zero. According to this embodiment, the MFB paths are located between the positive input end and the negative input end.

As shown in FIG. 3, the input module 210 further comprises an impedance component, which is a resistor Rc in this embodiment, coupled to a DC level DC1. In addition, the feedback module 222 is coupled to a DC level DC2 through an end of the capacitor C1. According to the present invention, the DC levels DC1, DC2, and DC3 are all AC ground, so either a plurality of DC levels out of the DC levels DC1, DC2 and DC3 can be substantially identical or the DC levels DC1, DC2 and DC3 can be not equal at all.

The operational principles of the filtering device 200 are described in the following. A node equation of the non-virtual ground input end vn1 can be written as follows:

$$\frac{Vo - vn 1}{R 3} + \frac{0 - vn 1}{R 2} + \frac{V 1 - vn 1}{Ra} + \frac{V 2 - vn 1}{Rb} + \frac{0 - vn 1}{Rc} + ( 0 - vn 1 ) * SC 1 = 0$$

where Ra, Rb, Rc, R2, and R3 represent resistance values of the resistors Ra, Rb, Rc, R2, and R3 respectively, C1 represents the capacitance value of the capacitor C1 mentioned above, and vn1 represents the voltage value of the non-virtual ground input end vn1 mentioned above. The equation mentioned above can be reduced further to a more simplified equation:

$$Vo * ( \frac{1}{R 3} ) = vn 1 * ( \frac{1}{R 3} + \frac{1}{R 2} + \frac{1}{Ra} + \frac{1}{Rb} + \frac{1}{Rc} + SC 1 ) - V 1 * ( \frac{1}{Ra} ) - V 2 * ( \frac{1}{Rb} ) \qquad ( 1 )$$

In addition, a node equation of the negative input end of the amplifier 224 can be written as follows:

$$( Vo - 0 ) * SC 2 = \frac{0 - vn 1}{R 2}$$

where C2 represents the capacitance value of capacitor C2 mentioned above. The equation mentioned above can be reduced further to arrive to the simplified equation:
vn1=−Vo*SC2R2 (2)

Substitution of Equation (2) into Equation (1) will show:

$$Vo = - V1 * ( \frac{R 3}{Ra} ) - V 2 * ( \frac{R 3}{Rb} ) + ( - Vo * SC 2 R 2 ) * R 3 * ( \frac{1}{R 3} + \frac{1}{R 2} + \frac{1}{Ra} + \frac{1}{Rb} + \frac{1}{Rc} + SC 1 ) \\ \to \\ Vo * [ 1 + SC 2 R 2 R 3 * ( \frac{1}{R 3} + \frac{1}{R 2} + \frac{1}{Ra} + \frac{1}{Rb} + \frac{1}{Rc} + SC 1 ) ] = - V 1 * ( \frac{R 3}{Ra} ) - V 2 * ( \frac{R 3}{Rb} ) \\ \to \\ Vo = \frac{- V 1 * ( \frac{R 3}{Ra} ) - V 2 * ( \frac{R 3}{Rb} )}{[ 1 + SC 2 R 2 R 3 * ( \frac{1}{R 3} + \frac{1}{R 2} + \frac{1}{Ra} + \frac{1}{Rb} + \frac{1}{Rc} + SC 1 ) ]} \\ = \frac{- V 1 * ( \frac{R 3}{Ra} ) - V 2 * ( \frac{R 3}{Rb} )}{[ 1 + SC 2 R 2 R 3 ( \frac{1}{R 3} + \frac{1}{R 2} + \frac{1}{Ra // Rb // Rc} ) + {S}^{2} C 1 C 2 R 2 R 3 ]} \qquad ( 3 )$$

In this form, we can identify characteristic parameters ω₀ and Q of the filtering device 200 as:

$${ϖ}_{0} = \frac{1}{\sqrt{C 1 C 2 R 2 R 3}} , Q = \frac{\sqrt{\frac{C 1}{C 2}}}{\sqrt{\frac{R 2}{R 3}} + \sqrt{\frac{R 3}{R 2}} + \sqrt{\frac{R 2 R 3}{{( Ra // Rb // Rc )}^{2}}}}$$

By replacing these parameters into Equation (3), we can show:

$$Vo = \frac{- V 1 * ( \frac{R 3}{Ra} ) - V 2 * ( \frac{R 3}{Rb} )}{1 + \frac{S}{Q * {ϖ}_{0}} + {( \frac{S}{{ϖ}_{0}} )}^{2}}$$

In addition, gain values G1 and G2 corresponding to the input signals V1 and V2 respectively, can be described by the following equations:

$$G 1 = \frac{Vo}{V 1} = - \frac{R 3}{Ra}$$

$$G 2 = \frac{Vo}{V 2} = - \frac{R 3}{Rb}$$

From the description above, the relative weighting of superposed input signals V1 and V2 can be implemented by properly selecting the resistance values of resistors Ra and Rb, where during the process of superposing the input signals V1 and V2, the gain values G1 and G2 corresponding to the input signals V1 and V2 can vary from each other. In addition, the characteristic parameter Q can be arbitrarily chosen by properly selecting the resistance value of resistor Rc. Therefore, although gain values G1 and G2 corresponding to input signals V1 and V2 can be adjusted as required, the present invention can invariably maintain an arbitrary Q value by appropriately selecting the resistance value of the resistor Rc. Here, the resistor Rc can be utilized for adjusting the quality factor of the filtering device, so resistor Rc can be considered a quality impedance component, whose impedance value (which is the resistance value in this embodiment) can be adjusted according to at least one of the other resistance values of the input module 210, i.e., the resistance value(s) of at least one of the resistors Ra and Rb.

In a variation of the first embodiment, resistors Ra and Rb are replaced by a plurality of impedance components coupled to at least one switch in order to select a set of gain values from a plurality of sets of gain values corresponding to the input signals V1 and V2. Additionally, in order to invariably maintain the Q value while selecting a set of gain values from the plurality of sets of gain values, the resistor Rc is replaced by a plurality of impedance components coupled to at least one switch. The impedance value(s) from the plurality of impedance components can be calculated in advance to match a given value for Rc in accordance with the plurality of sets of gain values corresponding to the input signals.

In another variation of the first embodiment, resistors Ra and Rb are respectively replaced by adjustable impedance components in order to select a set of gain values from a plurality of sets of gain values corresponding to the input signals V1 and V2. Additionally, in order to invariably maintain the Q value while selecting an arbitrary set of gain values from the plurality of sets of gain values, the resistor Rc is replaced by an adjustable impedance component. The range of the impedance value of this component can be properly selected in advance through calculations and measurements in accordance with the plurality of sets of gain values corresponding to the input signals.

In another variation of the first embodiment, resistors Ra and Rb are further coupled to adjustable impedance components in order to select a set of gain value from a plurality of sets of gain values corresponding to the input signals V1 and V2. Additionally, in order to invariably maintain the Q value while arbitrarily selecting a set of gain values from the plurality of sets of gain values, the resistor Rc is coupled to an adjustable impedance component, where the impedance value can be properly selected in advance through calculations and measurements in accordance with the plurality of sets of gain values corresponding to the input signals.

It is noted that although the filtering device of the first embodiment is implemented by utilizing the circuit configuration of impedance components Ra, Rb, Rc, R2, R3, C1, and C2 as shown in FIG. 3, this is not a limitation of the present invention. According to the present invention, the filtering device can be designed to be a low pass filtering device, a band pass filtering device, a band reject filtering device, or a high pass filtering device. Therefore, other kinds of circuit configurations can be applied to other embodiments of the present invention.

A second embodiment of the present invention is similar to the first embodiment, where the differences between the first and second embodiments are described as follows. In the second embodiment, the filtering device 200 is capable of filtering N input signals (V1, V2, . . . , VN) to generate the filtered signal Vo, and the resistors Ra and Rb in the input module 210 are replaced by N impedance components, for example, N resistors Ra-1, Ra-2, . . . , to Ra-N, where a first end of each resistor is utilized for inputting one of the N input signals (V1, V2, . . . , VN), and a second end of each resistor is coupled to the non-virtual ground input end vn1. Similarly, the filtering device of this embodiment also has the capability of superposing and filtering a plurality of input signals, which can be independent of each other/one another. In addition, with respect to the variations of the first embodiment, the second embodiment can be varied accordingly, where the descriptions related to the variations are not repeated for the second embodiment.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A filtering device for filtering N input signals to generate a filtered signal, the filtering device comprising:
an amplifier including an input end and an output end;
multiple feedback (MFB) paths coupling between the input end and the output end; and
a plurality of impedance components, each of the plurality of impedance components comprising a first end coupled to one of the N input signals and a second end coupled to the input end of the amplifier;
wherein N is an integer greater than one, and the voltage drops between the input end and each of the second ends are non-zero.

2. The filtering device of claim 1, wherein the N input signals are independent to each other.

3. The filtering device of claim 1, further comprising:
a quality impedance component including an end coupled to the impedance components for adjusting a quality factor of the filtering device.

4. The filtering device of claim 3, wherein an impedance value of the quality impedance component is adjusted according to at least one impedance value of at least one of the impedance components.

5. The filtering device of claim 1, wherein a gain value of each input signal of the N input signals is varied according to an impedance value of an impedance component coupled to the input signal.

6. The filtering device of claim 1, wherein the filtering device is a low pass filtering device, a band pass filtering device, a band reject filtering device, or a high pass filtering device.

7. The filtering device of claim 1, wherein impedance values of the impedance components are adjustable.

8. A filtering device for filtering and superposing a first input signal and a second input signal to generate a filtered signal, the filtering device comprising:
a first resistor including a first end for receiving the first input signal;
a second resistor including a first end for receiving the second input signal;
a feedback module coupled to a second end of the first resistor and a second end of the second resistor for providing multiple feedback (MFB) paths; and
an amplifier including an input end and an output end, the feedback module being coupled between the input end and the output end of the amplifier, the output end being utilized for outputting the filtered signal;
wherein the filtered signal is received as a feedback signal by the input end of the amplifier via the feedback module, and the voltage drop between the second end of the first or second resistor and the input end is non-zero.

9. The filtering device of claim 8, further comprising:
a third resistor coupled to the second ends of the first and second resistors and the feedback module for adjusting a quality factor of the filtering device.

10. The filtering device of claim 9, wherein a resistance value of the third resistor is adjusted according to a resistance value of the first resistor and/or a resistance value of the second resistor.

11. The filtering device of claim 8, wherein the filtering device is a low pass filtering device, a band pass filtering device, a band reject filtering device, or a high pass filtering device.

12. The filtering device of claim 8, wherein at least one of resistance values of the first, second, and third resistors is adjustable.

13. A filtering device for filtering and superposing N input signals to generate a filtered signal, the filtering device comprising:
an input module comprising N impedance components, each impedance component comprising a first end and a second end, the first end being utilized for receiving one of the N input signals; and
a first circuit comprising:
a non-virtual ground input end coupled to the second ends of the N impedance components; and
an amplifier including a first input end and an output end, wherein there are multiple feedback (MFB) paths between the first input end and the output end, the MFB paths are coupled to the non-virtual ground input end, and the output end of the amplifier is utilized for outputting the filtered signal;
wherein the input module and the first circuit form a MFB filter.

14. The filtering device of claim 13, wherein the input module further comprises:
a quality impedance component coupled to the impedance components for adjusting a quality factor of the filtering device.

15. The filtering device of claim 14, wherein an impedance value of the quality impedance component is adjusted according to at least one of impedance values of the other impedance components of the input module.

16. The filtering device of claim 13, wherein the input module further comprises an impedance component including a first end coupled to the non-virtual ground input end and a second end coupled to a first direct current (DC) level, and the MFB paths comprises:
a first resistor including a first end coupled to the non-virtual ground input end and a second end coupled to the first input end;
a second resistor including a first end coupled to the non-virtual ground input end and a second end coupled to the output end of the amplifier;
a first capacitor including a first end coupled to the non-virtual ground input end and a second end coupled to a second DC level; and
a second capacitor including a first end and a second end respectively coupled to the first input end and the output end of the amplifier;
wherein a second input end of the amplifier is coupled to a third DC level.

17. The filtering device of claim 16, wherein a plurality of DC levels out of the first, second, and third DC levels are substantially identical.

18. The filtering device of claim 16, wherein the first, second, and third DC levels are not equal at all.

19. The filtering device of claim 13, wherein the N input signals are independent to each other.

20. The filtering device of claim 13, wherein the voltage drop between the first input end of the amplifier and the non-virtual ground input end is non-zero.
